(19) United States
(12) Patent Application Publication
(10) Pub. No.: US 2026/0180530 A1
(43) Pub. Date: Jun. 25, 2026

(54) Amplifier circuit

(71) Applicant: REALTEK SEMICONDUCTOR CORPORATION, HSINCHU (TW)

(72) Inventor: SHIH-HSIUNG HUANG, HSINCHU (TW)

(21) Appl. No.: 19/398,325

(22) Filed: Nov. 24, 2025

(30) Foreign Application Priority Data
Dec. 20, 2024 (TW) 113150080

(51) Int. Cl. H03F 3/45

(52) U.S. Cl. CPC H03F 3/45188; H03F 2203/45024

(57) ABSTRACT

An amplifier circuit has first and second input terminals and first and second output terminals, and includes first and second inverter-based amplifiers and first and second output stages. The first inverter-based amplifier has third and fourth output terminals. The second inverter-based amplifier has fifth and sixth output terminals. The first and the second input terminal are the two input terminals of the first and second inverter-based amplifier. The first and second inverter-based amplifiers are respectively coupled to first and second voltages. The first output stage is coupled to the third and fourth output terminals. The second output stage is coupled to the fifth and sixth output terminals. The first and second output terminals are the output terminals of the first and second output stages, respectively.

### BACKGROUND OF THE INVENTION

### 1. Field of the Invention

The present invention generally relates to amplifiers.

### 2. Description of Related Art

Amplifiers are commonly found in electronic products and are used to amplify signals. A conventional amplifier usually contains an amplifier circuit and multiple subsequent-stage circuits, but the bias of the output signal from the amplifier circuit does not necessarily satisfy the input common-mode bias of these subsequent-stage circuits simultaneously. Such disadvantages limit the application range of the amplifier.

### SUMMARY OF THE INVENTION

In view of the issues of the prior art, an object of the present invention is to provide an amplifier circuit, so as to make an improvement to the prior art.

According to one aspect of the present invention, an amplifier circuit is provided. The amplifier circuit has a first input terminal, a second input terminal, a first output terminal, and a second output terminal, and includes a first inverter-based amplifier, a second inverter-based amplifier, a first output stage, and a second output stage. The first inverter-based amplifier has a third output terminal and a fourth output terminal, wherein the first input terminal and the second input terminal are the two input terminals of the first inverter-based amplifier, and the first inverter-based amplifier is coupled to a first voltage. The second inverter-based amplifier has a fifth output terminal and a sixth output terminal, wherein the first input terminal and the second input terminal are the two input terminals of the second inverter-based amplifier, and the second inverter-based amplifier is coupled to a second voltage. The first output stage is coupled to the third output terminal and the fourth output terminal, wherein the first output terminal is one of the output terminals of the first output stage. The second output stage is coupled to the fifth output terminal and the sixth output terminal, wherein the second output terminal is one of the output terminals of the second output stage.

The technical means embodied in the embodiments of the present invention can solve at least one of the problems of the prior art. Therefore, compared to the prior art, the present invention can have a wider range of applications.

These and other objectives of the present invention no doubt become obvious to those of ordinary skill in the art after reading the following detailed description of the preferred embodiments with reference to the various figures and drawings.

### BRIEF DESCRIPTION OF THE DRAWINGS

FIG. 1 is the circuit diagram of an amplifier circuit according to an embodiment of the present invention.

FIG. 2 is the circuit diagram of an amplifier circuit according to another embodiment of the present invention.

FIG. 3 is the circuit diagram of an amplifier circuit according to another embodiment of the present invention.

FIG. 4 is the circuit diagram of an amplifier circuit according to another embodiment of the present invention.

FIG. 5 is the circuit diagram of an amplifier circuit according to another embodiment of the present invention.

FIG. 6 is the circuit diagram of the stacking amplifier according to another embodiment of the present invention.

FIG. 7 is the circuit diagram of a stacking amplifier according to another embodiment of the present invention.

FIG. 8A is the circuit diagram of the level shifter circuit according to an embodiment of the present invention.

FIG. 8B is a circuit diagram of the level shifter circuit according to another embodiment of the present invention.

FIG. 9 is the circuit diagram of the stacking amplifier according to another embodiment of the present invention.

FIG. 10 is a circuit diagram of a stacking amplifier according to another embodiment of the present invention.

FIG. 11 is the circuit diagram of an inverter-based amplifier according to another embodiment of the present invention.

### DETAILED DESCRIPTION OF THE EMBODIMENTS

The following description is written by referring to terms of this technical field. If any term is defined in this specification, such term should be interpreted accordingly. In addition, the connection between objects or events in the below-described embodiments can be direct or indirect provided that these embodiments are practicable under such connection. Said “indirect” means that an intermediate object or a physical space exists between the objects, or an intermediate event or a time interval exists between the events.

The disclosure herein includes amplifier circuits. On account of that some or all elements of the amplifier circuits could be known, the detail of such elements is omitted provided that such detail has little to do with the features of this disclosure, and that this omission nowhere dissatisfies the specification and enablement requirements. A person having ordinary skill in the art can choose components or steps equivalent to those described in this specification to carry out the present invention, which means that the scope of this invention is not limited to the embodiments in the specification.

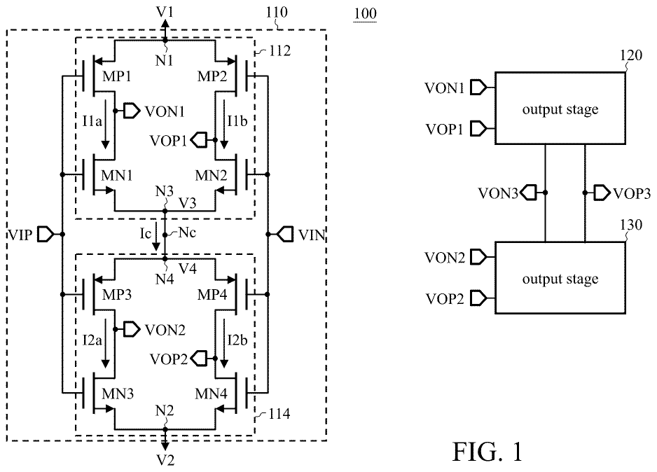

Reference is made to the FIG. 1, which is a circuit diagram of an amplifier circuit according to an embodiment of the present invention. The amplifier circuit 100 includes a stacking amplifier 110, an output stage 120, and an output stage 130. An input terminal VIP and an input terminal VIN are the input terminals of the amplifier circuit 100, and an output terminal VOP3 and an output terminal VON3 are the output terminals of the amplifier circuit 100.

The stacking amplifier 110 includes an inverter-based amplifier 112 and an inverter-based amplifier 114. The input terminal VIP and the input terminal VIN are the input terminals of the inverter-based amplifier 112, and an output terminal VOP1 and an output terminal VON1 are the output terminals of the inverter-based amplifier 112. The input terminal VIP and the input terminal VIN are the input terminals of the inverter-based amplifier 114, and an output terminal VOP2 and an output terminal VON2 are the output terminals of the inverter-based amplifier 114.

The output stage 120 is coupled to the output terminal VOP1 and the output terminal VON1, wherein the output terminal VOP3 is one of the output terminals of the output stage 120. The output stage 130 is coupled to the output terminal VOP2 and the output terminal VON2, wherein the output terminal VON3 is one of the output terminals of the output stage 130.

The inverter-based amplifier 112 includes a P-channel Metal-Oxide-Semiconductor Field-Effect Transistor (hereinafter referred to as a PMOS transistor) MP1, a PMOS transistor MP2, an N-channel Metal-Oxide-Semiconductor Field-Effect Transistor (hereinafter referred to as an NMOS transistor) MN1, and an NMOS transistor MN2.

The inverter-based amplifier 114 includes a PMOS transistor MP3, a PMOS transistor MP4, an NMOS transistor MN3, and an NMOS transistor MN4.

The gates of the PMOS transistor MP1, the NMOS transistor MN1, the PMOS transistor MP3, and the NMOS transistor MN3 are coupled or electrically connected to the input terminal VIP. The gates of the PMOS transistor MP2, the NMOS transistor MN2, the PMOS transistor MP4, and the NMOS transistor MN4 are coupled or electrically connected to the input terminal VIN.

The sources of the PMOS transistor MP1 and the PMOS transistor MP2 are coupled or electrically connected to a voltage V1. The sources of the NMOS transistor MN1 and the NMOS transistor MN2 are coupled or electrically connected to a node Nc. The drains of the PMOS transistor MP1 and the NMOS transistor MN1 are coupled or electrically connected to the output terminal VON1. The drains of the PMOS transistor MP2 and the NMOS transistor MN2 are coupled or electrically connected to the output terminal VOP1.

The sources of the PMOS transistor MP3 and the PMOS transistor MP4 are coupled or electrically connected to the node Nc. The sources of the NMOS transistor MN3 and the NMOS transistor MN4 are coupled or electrically connected to a voltage V2. The drains of the PMOS transistor MP3 and the NMOS transistor MN3 are coupled or electrically connected to the output terminal VON2. The drains of the PMOS transistor MP4 and the NMOS transistor MN4 are coupled or electrically connected to the output terminal VOP2.

The inverter-based amplifier 112 includes four input terminals (i.e., the gates of four transistors), two output terminals (VON1 and VOP1), and two nodes (N1 and N3). The inverter-based amplifier 114 includes four input terminals (i.e., the gates of four transistors), two output terminals (VON2 and VOP2), and two nodes (N2 and N4). The voltage V1 is the voltage at the node N1. The voltage V2 is the voltage at the node N2. The intermediate voltage V3 is the voltage at the node N3. The intermediate voltage V4 is the voltage at the node N4. By adjusting the voltage V1, the voltage V2, the intermediate voltage V3 and/or the intermediate voltage V4, the bias of the inverter-based amplifier 112 and/or the bias of the inverter-based amplifier 114 can be adjusted. In the embodiment of FIG. 1, the node N3 and the node N4 are the same node (the node Nc) (i.e., V3 equals V4).

In some embodiments, the input terminal VIP and the input terminal VIN receive a pair of differential signals, such that the alternating current (AC) component of the intermediate voltage V3 and the AC component of the intermediate voltage V4 are both substantially zero.

The inverter-based amplifier 112 and the inverter-based amplifier 114 present a stacking structure. The voltage V1 is greater than the voltage V2, and the intermediate voltage V3 and the intermediate voltage V4 are less than the voltage V1 and greater than the voltage V2.

During operation, the total current (I1a+I1b) flowing through the inverter-based amplifier 112 is substantially equal to the current Ic flowing through the node Nc, and the total current (I2a+I2b) flowing through the inverter-based amplifier 114 is also substantially equal to the current Ic. In other words, I1a+I1b=I2a+I2b. The advantage of such a design is that it can reuse the current. Therefore, not only is no additional current needed, but the gain of the stacking amplifier 110 can also be increased.

Reference is made to FIG. 1. The bias of the output signals of the inverter-based amplifier 112 (i.e., the common-mode voltage of the differential output signals at the output terminal VOP1 and the output terminal VON1) can be made not equal to the bias of the output signals of the inverter-based amplifier 114 (i.e., the common-mode voltage of the differential output signals at the output terminal VOP2 and the output terminal VON2) by adjusting the aspect ratio of the transistors. In this way, the input common-mode bias of the output stage 120 and the input common-mode bias of the output stage 130 can be satisfied simultaneously.

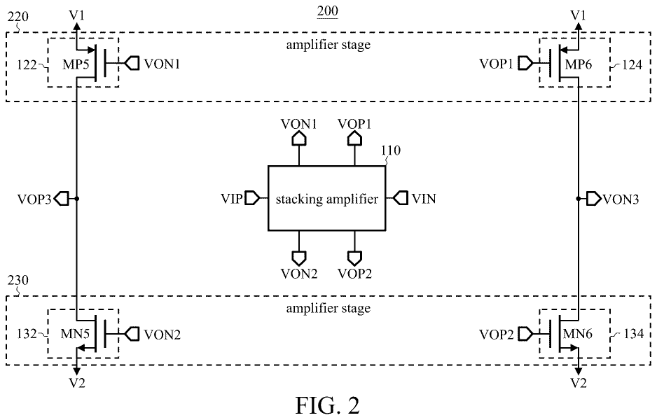

Reference is made to FIG. 2, which is the circuit diagram of an amplifier circuit according to another embodiment of the present invention. An amplifier circuit 200 includes the stacking amplifier 110, an amplifier stage 220, and an amplifier stage 230. The amplifier stage 220 and the amplifier stage 230 can serve as the output stages of the stacking amplifier 110 (corresponding to the output stage 120 and the output stage 130 in FIG. 1, respectively). The amplifier stage 220 includes an amplifier circuit 122 and an amplifier circuit 124. The amplifier circuit 122 amplifies the signal on the output terminal VON1, while the amplifier circuit 124 amplifies the signal on the output terminal VOP1. The signal amplified by the amplifier circuit 122 and the signal amplified by the amplifier circuit 124 are output from the output terminal VOP3 and the output terminal VON3, respectively.

The amplifier circuit 122 can be embodied by a PMOS transistor MP5. The source of the PMOS transistor MP5 is coupled or electrically connected to the voltage V1; the gate of the PMOS transistor MP5 is coupled or electrically connected to the output terminal VON1; the drain of the PMOS transistor MP5 is coupled or electrically connected to the output terminal VOP3.

The amplifier circuit 124 can be embodied by a PMOS transistor MP6. The source of the PMOS transistor MP6 is coupled or electrically connected to the voltage V1; the gate of the PMOS transistor MP6 is coupled or electrically connected to the output terminal VOP1; the drain of the PMOS transistor MP6 is coupled or electrically connected to the output terminal VON3.

The amplifier stage 230 includes an amplifier circuit 132 and an amplifier circuit 134. The amplifier circuit 132 amplifies the signal on the output terminal VON2, and the amplifier circuit 134 amplifies the signal on the output terminal VOP2. The signal amplified by the amplifier circuit 132 and the signal amplified by the amplifier circuit 134 are output from the output terminal VOP3 and the output terminal VON3, respectively.

The amplifier circuit 132 can be embodied by an NMOS transistor MN5. The source of the NMOS transistor MN5 is coupled or electrically connected to the voltage V2; the gate of the NMOS transistor MN5 is coupled or electrically connected to the output terminal VON2; the drain of the NMOS transistor MN5 is coupled or electrically connected to the output terminal VOP3.

The amplifier circuit 134 can be embodied by an NMOS transistor MN6. The source of the NMOS transistor MN6 is coupled or electrically connected to the voltage V2; the gate of the NMOS transistor MN6 is coupled or electrically connected to the output terminal VOP2; the drain of the NMOS transistor MN6 is coupled or electrically connected to the output terminal VON3.

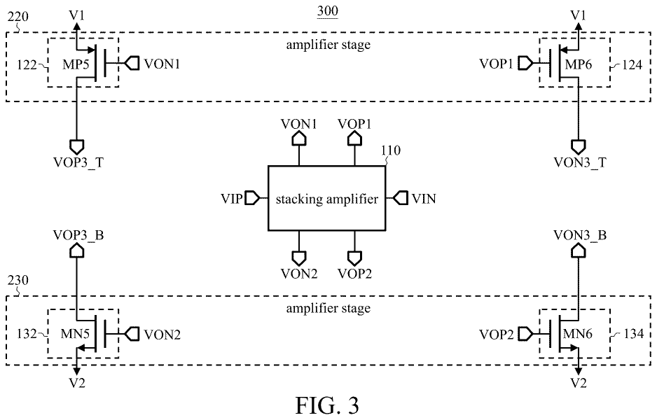

Reference is made to FIG. 3, which is the circuit diagram of an amplifier circuit according to another embodiment of the present invention. The amplifier circuit 300 includes the stacking amplifier 110, the amplifier stage 220, and the amplifier stage 230. The input terminals VIP and VIN are the input terminals of the amplifier circuit 300, and the output terminals VOP3_T, VOP3_B, VON3_T, and VON3_B are the output terminals of the amplifier circuit 300.

The amplifier circuit 300 is similar to the amplifier circuit 200, except that the drain of the PMOS transistor MP5 is coupled or electrically connected to the output terminal VOP3_T, the drain of the PMOS transistor MP6 is coupled or electrically connected to the output terminal VON3_T, the drain of the NMOS transistor MN5 is coupled or electrically connected to the output terminal VOP3_B, and the drain of the NMOS transistor MN6 is coupled or electrically connected to the output terminal VON3_B.

The amplifier circuit 122 amplifies the signal on the output terminal VON1, and the amplified signal is output from the output terminal VOP3_T. The amplifier circuit 124 amplifies the signal on the output terminal VOP1, and the amplified signal is output from the output terminal VON3_T. The amplifier circuit 132 amplifies the signal on the output terminal VON2, and the amplified signal is output from the output terminal VOP3_B. The amplifier circuit 134 amplifies the signal on the output terminal VOP2, and the amplified signal is output from the output terminal VON3_B.

Compared to the amplifier circuit 200, in the amplifier circuit 300, the output common-mode voltage of the amplifier stage 220 may not be equal to the output common-mode voltage of the amplifier stage 230, increasing the flexibility of the circuit design.

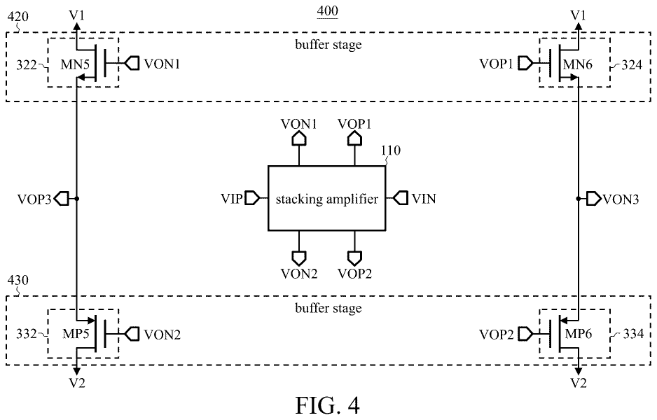

Reference is made to FIG. 4, which is the circuit diagram of the amplifier circuit according to another embodiment of the present invention. The amplifier circuit 400 includes the stacking amplifier 110, a buffer stage 420, and a buffer stage 430. The buffer stage 420 and the buffer stage 430 can serve as the output stages of the stacking amplifier 110 (corresponding to the output stage 120 and the output stage 130 in FIG. 1, respectively). The input terminal VIP and the input terminal VIN are the input terminals of the amplifier circuit 400, and the output terminal VOP3 and the output terminal VON3 are the output terminals of the amplifier circuit 400.

The buffer stage 420 includes the buffer circuit 322 and the buffer circuit 324, while the buffer stage 430 includes the buffer circuit 332 and the buffer circuit 334. The buffer circuits 322, 324, 332, and 334 can provide a relatively low output impedance and enhance the driving capability of the amplifier circuit 300 to the subsequent-stage circuit. In some embodiments, the buffer circuits 322, 324, 332, and 334 can be embodied by source followers.

The buffer circuit 322 can be embodied by the NMOS transistor MN5. The source of the NMOS transistor MN5 is coupled or electrically connected to the output terminal VOP3; the gate of the NMOS transistor MN5 is coupled or electrically connected to the output terminal VON1; the drain of the NMOS transistor MN5 is coupled or electrically connected to the voltage V1.

The buffer circuit 324 can be embodied by the NMOS transistor MN6. The source of the NMOS transistor MN6 is coupled or electrically connected to the output terminal VON3; the gate of the NMOS transistor MN6 is coupled or electrically connected to the output terminal VOP1; the drain of the NMOS transistor MN6 is coupled or electrically connected to the voltage V1.

The buffer circuit 332 can be embodied by the PMOS transistor MP5. The source of the PMOS transistor MP5 is coupled or electrically connected to the output terminal VOP3; the gate of the PMOS transistor MP5 is coupled or electrically connected to the output terminal VON2; the drain of the PMOS transistor MP5 is coupled or electrically connected to the voltage V2.

The buffer circuit 334 can be embodied by the PMOS transistor MP6. The source of the PMOS transistor MP6 is coupled or electrically connected to the output terminal VON3; the gate of the PMOS transistor MP6 is coupled or electrically connected to the output terminal VOP2; the drain of the PMOS transistor MP6 is coupled or electrically connected to the voltage V2.

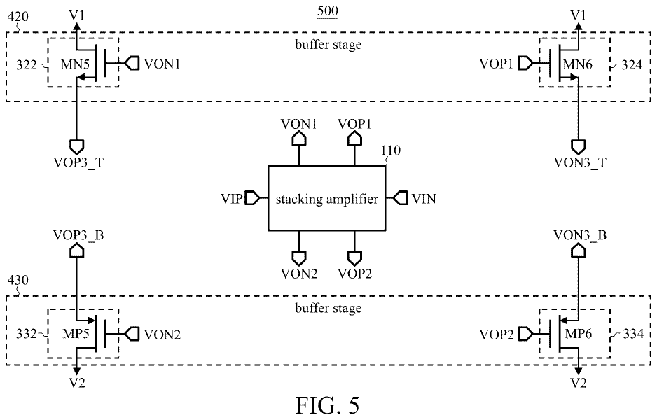

Reference is made to FIG. 5, which is the circuit diagram of an amplifier circuit according to another embodiment of the present invention. The amplifier circuit 500 includes the stacking amplifier 110, the buffer stage 420, and the buffer stage 430. The input terminals VIP and VIN are the input terminals of the amplifier circuit 500, while the output terminals VOP3_T, VOP3_B, VON3_T, and VON3_B are the output terminals of the amplifier circuit 500.

The amplifier circuit 500 is similar to the amplifier circuit 400, except that the source of the NMOS transistor MN5 is coupled or electrically connected to the output terminal VOP3_T, the source of the NMOS transistor MN6 is coupled or electrically connected to the output terminal VON3_T, the source of the PMOS transistor MP5 is coupled or electrically connected to the output terminal VOP3_B, and the source of the PMOS transistor MP6 is coupled or electrically connected to the output terminal VON3_B.

Compared to the amplifier circuit 400, in the amplifier circuit 500, the output common-mode voltage of the buffer stage 420 may not be equal to the output common-mode voltage of the buffer stage 430, increasing the flexibility of the circuit design.

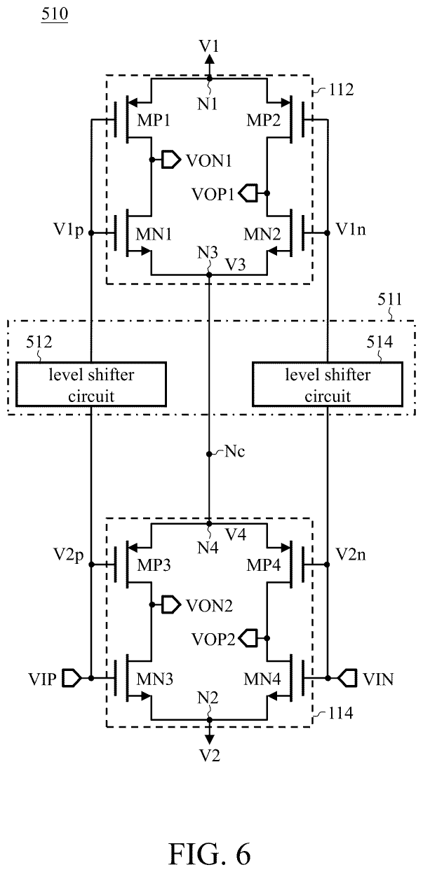

Reference is made to FIG. 6, which is the circuit diagram of the stacking amplifier according to another embodiment of the present invention. The stacking amplifier 510 includes the inverter-based amplifier 112, the inverter-based amplifier 114, and the level shifter 511, all of which are coupled to one another.

The level shifter 511 includes a level shifter circuit 512 and a level shifter circuit 514, and is configured to receive the input signals V2p and V2n and to generate the input signals V1p and V1n. The level shifter 511 is coupled or electrically connected to the input terminals of the inverter-based amplifier 112 and the input terminals of the inverter-based amplifier 114. The level shifter circuit 512 is coupled to the inverter-based amplifier 112 and the inverter-based amplifier 114, and is configured to receive the input signal V2p and generate the input signal V1p. The level shifter circuit 514 is coupled to the inverter-based amplifier 112 and the inverter-based amplifier 114, and is configured to receive the input signal V2n and generate the input signal V1n. More specifically, one terminal of the level shifter circuit 512 is coupled or electrically connected to the gates of the PMOS transistor MP1 and the NMOS transistor MN1; the other terminal of the level shifter circuit 512 is coupled or electrically connected to the gates of the PMOS transistor MP3 and the NMOS transistor MN3. One terminal of the level shifter circuit 514 is coupled or electrically connected to the gates of the PMOS transistor MP2 and the NMOS transistor MN2; the other terminal of the level shifter circuit 514 is coupled or electrically connected to the gates of the PMOS transistor MP4 and the NMOS transistor MN4.

The purpose of the level shifter 511 is to make the common-mode voltage Vcm1 of the differential input signals (V1p and V1n) of the inverter-based amplifier 112 not equal to the common-mode voltage Vcm2 of the differential input signals (V2p and V2n) of the inverter-based amplifier 114, which can increase the flexibility of the circuit design. In some embodiments, the input signal V1p and the input signal V2p have the same AC component. The input signal V1n and the input signal V2n have the same AC component.

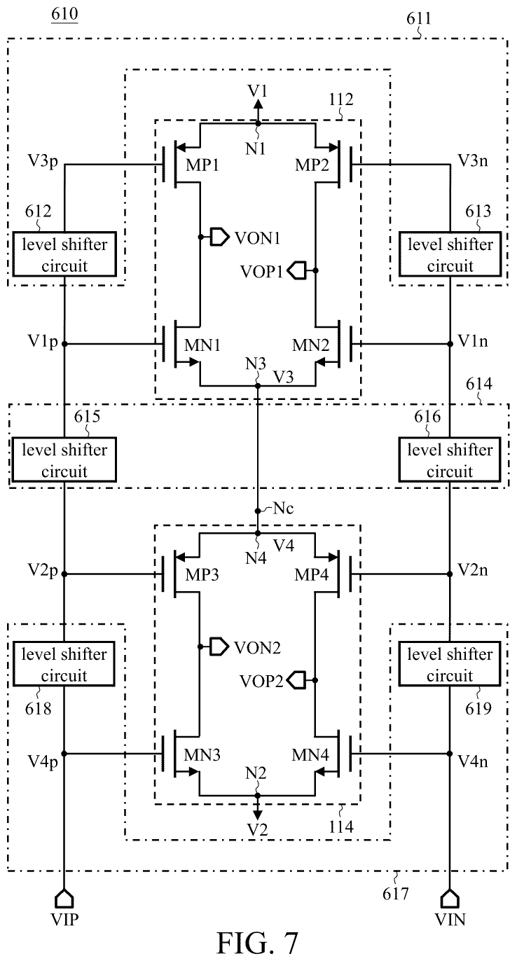

Reference is made to FIG. 7, which is the circuit diagram of a stacking amplifier according to another embodiment of the present invention. The stacking amplifier 610 includes the inverter-based amplifier 112, the inverter-based amplifier 114, a level shifter 611, a level shifter 614, and a level shifter 617, all of which are coupled to one another.

The level shifter 611 includes a level shifter circuit 612 and a level shifter circuit 613, and is configured to receive the input signals V1p and V1n and to generate the input signals V3p and V3n. The level shifter 611 is coupled or electrically connected to the gates of the PMOS transistor MP1, the PMOS transistor MP2, the NMOS transistor MN1, and the NMOS transistor MN2. More specifically, one terminal of the level shifter circuit 612 is coupled or electrically connected to the gate of the PMOS transistor MP1; the other terminal of the level shifter circuit 612 is coupled or electrically connected to the gate of the NMOS transistor MN1. One terminal of the level shifter circuit 613 is coupled or electrically connected to the gate of the PMOS transistor MP2; the other terminal of the level shifter circuit 613 is coupled or electrically connected to the gate of the NMOS transistor MN2.

The level shifter circuit 612 receives the input signal V1p and generates the input signal V3p. The level shifter circuit 613 receives the input signal V1n and generates the input signal V3n. The input signal V1p and the input signal V1n are respectively input to the gates of the NMOS transistor MN1 and the NMOS transistor MN2. The input signal V3p and the input signal V3n are respectively input to the gates of the PMOS transistor MP1 and the PMOS transistor MP2.

The level shifter 614 includes a level shifter circuit 615 and a level shifter circuit 616. One terminal of the level shifter 614 is coupled or electrically connected to the gates of the NMOS transistor MN1 and the NMOS transistor MN2; the other terminal of the level shifter 614 is coupled or electrically connected to the gates of the PMOS transistor MP3 and the PMOS transistor MP4. More specifically, one terminal of the level shifter circuit 615 is coupled or electrically connected to the gate of the NMOS transistor MN1; the other terminal of the level shifter circuit 615 is coupled or electrically connected to the gate of the PMOS transistor MP3. One terminal of the level shifter circuit 616 is coupled or electrically connected to the gate of the NMOS transistor MN2; the other terminal of the level shifter circuit 616 is coupled or electrically connected to the gate of the PMOS transistor MP4. The function of the level shifter 614 is similar to that of the level shifter 511.

The level shifter 617 includes a level shifter circuit 618 and a level shifter circuit 619, and is configured to receive the input signals V4p and V4n and to generate the input signals V2p and V2n. The level shifter 617 is coupled or electrically connected to the gates of the PMOS transistor MP3, the PMOS transistor MP4, the NMOS transistor MN3, and the NMOS transistor MN4. More specifically, one terminal of the level shifter circuit 618 is coupled or electrically connected to the gate of the PMOS transistor MP3; the other terminal of the level shifter circuit 618 is coupled or electrically connected to the gate of the NMOS transistor MN3. One terminal of the level shifter circuit 619 is coupled or electrically connected to the gate of the PMOS transistor MP4; the other terminal of the level shifter circuit 619 is coupled or electrically connected to the gate of the NMOS transistor MN4.

The level shifter circuit 618 receives the input signal V4p and generates the input signal V2p. The level shifter circuit 619 receives the input signal V4n and generates the input signal V2n. The input signal V4p and the input signal V4n are respectively input to the gate of the NMOS transistor MN3 and the gate of the NMOS transistor MN4. The input signal V2p and the input signal V2n are respectively input to the gate of the PMOS transistor MP3 and the gate of the PMOS transistor MP4.

The level shifter 611, the level shifter 614, and the level shifter 617 aim to adjust the common-mode voltage of the input signal, similar to the level shifter 511. In some embodiments, the common-mode voltage Vcm1 of the input signal V1p and the input signal V1n, the common-mode voltage Vcm2 of the input signal V2p and the input signal V2n, the common-mode voltage Vcm3 of the input signal V3p and the input signal V3n, and the common-mode voltage Vcm4 of the input signal V4p and the input signal V4n may not be the same.

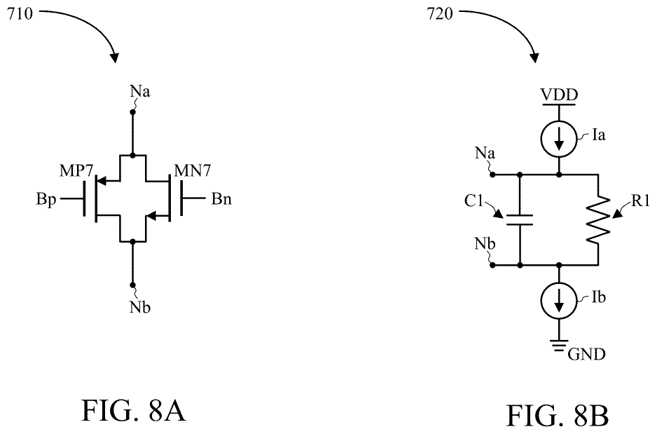

Reference is made to FIG. 8A, which is the circuit diagram of a level shifter circuit according to an embodiment of the present invention. A level shifter circuit 710 includes a PMOS transistor MP7 and an NMOS transistor MN7. The gate of the PMOS transistor MP7 receives a bias Bp. The gate of the NMOS transistor MN7 receives a bias Bn. The node Na and the node Nb are the two terminals of the level shifter circuit 710.

Reference is made to FIG. 8B, which is the circuit diagram of a level shifter circuit according to another embodiment of the present invention. The level shifter circuit 720 includes a current source Ia, a current source Ib, a capacitor C1, and a resistor R1. One terminal of the current source Ia is coupled or electrically connected to the power supply voltage VDD; the other terminal of the current source Ia is coupled or electrically connected to the node Na. The capacitor C1 and the resistor R1 are coupled between the node Na and the node Nb. One terminal of the current source Ib is coupled or electrically connected to the node Nb; the other terminal of the current source Ib is coupled or electrically connected to the reference voltage GND (e.g., ground). The node Na and the node Nb are the two terminals of the level shifter circuit 720.

The level shifter circuits in FIG. 6 and FIG. 7 can be embodied by the level shifter circuit 710 or the level shifter circuit 720.

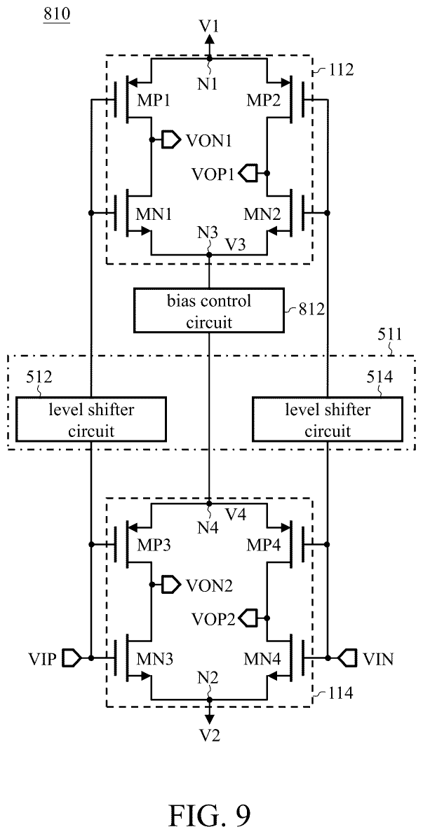

Reference is made to FIG. 9, which is the circuit diagram of a stacking amplifier according to another embodiment of the present invention. The stacking amplifier 810 includes the inverter-based amplifier 112, the inverter-based amplifier 114, the level shifter 511, and the bias control circuit 812, all of which are coupled to one another. The bias control circuit 812 is coupled or electrically connected to the node N3 of the inverter-based amplifier 112 and the node N4 of the inverter-based amplifier 114. The bias control circuit 812 facilitates easy adjustment of the bias conditions of the inverter-based amplifier 112 and/or the inverter-based amplifier 114 (i.e., adjusting the intermediate voltage V3 and/or the intermediate voltage V4). The AC component of the intermediate voltage V3 is substantially zero, and the AC component of the intermediate voltage V4 is substantially zero.

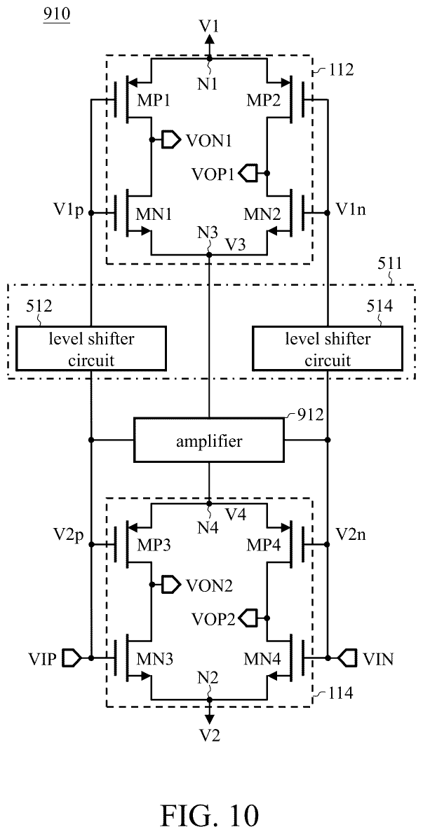

Reference is made to FIG. 10, which is the circuit diagram of the stacking amplifier according to another embodiment of the present invention. The stacking amplifier 910 includes the inverter-based amplifier 112, the inverter-based amplifier 114, the level shifter 511, and an amplifier 912, all of which are coupled to one another. The amplifier 912 is coupled between the inverter-based amplifier 112 and the inverter-based amplifier 114, and is further coupled to the level shifter circuit 512, the level shifter circuit 514, the gate of the NMOS transistor MN3, the gate of the PMOS transistor MP3, the gate of the NMOS transistor MN4, and the gate of the PMOS transistor MP4. More specifically, the amplifier 912 is coupled or electrically connected to the node N3 and the node N4, and is configured to amplify the input signal V2p and the input signal V2n. The AC component of the intermediate voltage V3 is substantially zero, and the AC component of the intermediate voltage V4 is substantially zero. In some embodiments, the amplifier 912 is an inverter-based amplifier.

The stacking amplifier 110 in FIGS. 1 to 5 can also be replaced by the stacking amplifier 510, the stacking amplifier 610, the stacking amplifier 810, or the stacking amplifier 910.

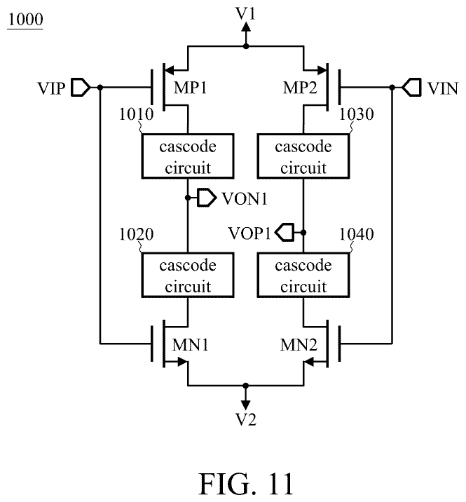

Reference is made to FIG. 11, which is the circuit diagram of an inverter-based amplifier according to another embodiment of the present invention. The inverter-based amplifier 1000 includes the PMOS transistor MP1, the NMOS transistor MN1, the PMOS transistor MP2, the NMOS transistor MN2, a cascode circuit 1010, a cascode circuit 1020, a cascode circuit 1030, and a cascode circuit 1040. The cascode circuit 1010 is coupled between the drain of the PMOS transistor MP1 and the output terminal VON1. The cascode circuit 1020 is coupled between the drain of the NMOS transistor MN1 and the output terminal VON1. The cascode circuit 1030 is coupled between the drain of the PMOS transistor MP2 and the output terminal VOP1. The cascode circuit 1040 is coupled between the drain of the NMOS transistor MN2 and the output terminal VOP1.

Compared to the inverter-based amplifier 112 (or 114), the inverter-based amplifier 1000 has a greater gain. In some embodiments, the cascode circuits 1010 to 1040 can be embodied by Metal-Oxide-Semiconductor Field-Effect Transistors (MOSFETs). This is well known to people having ordinary skill in the art, so further elaboration is omitted for brevity.

In other embodiments, the aforementioned inverter-based amplifier 112 and/or the inverter-based amplifier 114 may be replaced by the inverter-based amplifier 1000.

Note that the shape, size, and ratio of any element in the disclosed figures are exemplary for understanding, not for limiting the scope of this invention.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. An amplifier circuit having a first input terminal, a second input terminal, a first output terminal, and a second output terminal, the amplifier circuit comprising:
a first inverter-based amplifier having a third output terminal and a fourth output terminal, wherein the first input terminal and the second input terminal are two input terminals of the first inverter-based amplifier, and the first inverter-based amplifier is coupled to a first voltage;
a second inverter-based amplifier having a fifth output terminal and a sixth output terminal, wherein the first input terminal and the second input terminal are two input terminals of the second inverter-based amplifier, and the second inverter-based amplifier is coupled to a second voltage;
a first output stage coupled to the third output terminal and the fourth output terminal, wherein the first output terminal is an output terminal of the first output stage; and
a second output stage coupled to the fifth output terminal and the sixth output terminal, wherein the second output terminal is an output terminal of the second output stage.

2. The amplifier circuit of claim 1, wherein the first output stage and the second output stage are respectively a first amplifier stage and a second amplifier stage, the first amplifier stage comprises:
a first transistor having a first source, a first gate, and a first drain, wherein the first source is coupled to the first voltage, and the first gate is coupled to the fourth output terminal; and
a second transistor having a second source, a second gate, and a second drain, wherein the second source is coupled to the first voltage, and the second gate is coupled to the third output terminal; and
the second amplifier stage comprises:
a third transistor having a third source, a third gate, and a third drain, wherein the third source is coupled to the second voltage, and the third gate is coupled to the sixth output terminal; and
a fourth transistor having a fourth source, a fourth gate, and a fourth drain, wherein the fourth source is coupled to the second voltage, and the fourth gate is coupled to the fifth output terminal.

3. The amplifier circuit of claim 2, wherein the first drain is the first output terminal, the second drain is the second output terminal, the third drain is the first output terminal, and the fourth drain is the second output terminal.

4. The amplifier circuit of claim 2, wherein the amplifier circuit further comprises a seventh output terminal and an eighth output terminal, the first drain is the first output terminal, the second drain is the eighth output terminal, the third drain is the seventh output terminal, and the fourth drain is the second output terminal.

5. The amplifier circuit of claim 1, wherein the first output stage and the second output stage are respectively a first buffer stage and a second buffer stage, the first buffer stage comprises:
a first transistor having a first source, a first gate, and a first drain, wherein the first drain is coupled to the first voltage, and the first gate is coupled to the fourth output terminal; and
a second transistor having a second source, a second gate, and a second drain, wherein the second drain is coupled to the first voltage, and the second gate is coupled to the third output terminal; and
the second buffer stage comprises:
a third transistor having a third source, a third gate, and a third drain, wherein the third drain is coupled to the second voltage, and the third gate is coupled to the sixth output terminal; and
a fourth transistor having a fourth source, a fourth gate, and a fourth drain, wherein the fourth drain is coupled to the second voltage, and the fourth gate is coupled to the fifth output terminal.

6. The amplifier circuit of claim 5, wherein the first source is the first output terminal, the second source is the second output terminal, the third source is the first output terminal, and the fourth source is the second output terminal.

7. The amplifier circuit of claim 5, wherein the amplifier circuit further comprises a seventh output terminal and an eighth output terminal, the first source is the first output terminal, the second source is the eighth output terminal, the third source is the seventh output terminal, and the fourth source is the second output terminal.

8. The amplifier circuit of claim 1, wherein the first inverter-based amplifier has a first node and a second node, the second inverter-based amplifier has a third node and a fourth node, the first node is coupled to the first voltage, the third node is coupled to the second voltage, the second node has a first intermediate voltage, the fourth node has a second intermediate voltage, the first voltage is greater than the first intermediate voltage and the second intermediate voltage, and the first intermediate voltage and the second intermediate voltage are greater than the second voltage.

9. The amplifier circuit of claim 8, wherein the first input terminal and the second input terminal receive a pair of differential signals, an alternating current (AC) component of the first intermediate voltage is substantially zero, and an AC component of the second intermediate voltage is substantially zero.

10. The amplifier circuit of claim 8, wherein the second node and the fourth node are a same node.

11. The amplifier circuit of claim 8, wherein a first current flowing through the second node is substantially equal to a second current flowing through the first inverter-based amplifier, and the first current is substantially equal to a third current flowing through the second inverter-based amplifier.

12. The amplifier circuit of claim 8, wherein the first inverter-based amplifier comprises:
a first transistor having a first source, a first gate, and a first drain, wherein the first source is the first node, the first gate is the first input terminal, and the first drain is the fourth output terminal;
a second transistor having a second source, a second gate, and a second drain, wherein the second source is the second node, the second gate is the first input terminal, and the second drain is the fourth output terminal;
a third transistor having a third source, a third gate, and a third drain, wherein the third source is the first node, the third gate is the second input terminal, and the third drain is the third output terminal; and
a fourth transistor having a fourth source, a fourth gate, and a fourth drain, wherein the fourth source is the second node, the fourth gate is the second input terminal, and the fourth drain is the third output terminal.

13. The amplifier circuit of claim 12, wherein the second inverter-based amplifier comprises:
a fifth transistor, having a fifth source, a fifth gate, and a fifth drain, wherein the fifth source is the fourth node, the fifth gate is the first input terminal, and the fifth drain is the sixth output terminal;
a sixth transistor having a sixth source, a sixth gate, and a sixth drain, wherein the sixth source is the third node, the sixth gate is the first input terminal, and the sixth drain is the sixth output terminal;
a seventh transistor having a seventh source, a seventh gate, and a seventh drain, wherein the seventh source is the fourth node, the seventh gate is the second input terminal, and the seventh drain is the fifth output terminal; and
an eighth transistor having an eighth source, an eighth gate, and an eighth drain, wherein the eighth source is the third node, the eighth gate is the second input terminal, and the eighth drain is the fifth output terminal.

14. The amplifier circuit of claim 1, wherein the first inverter-based amplifier receives a first input signal and a second input signal, the second inverter-based amplifier receives a third input signal and a fourth input signal, and the amplifier circuit further comprises:
a level shifter coupled to the first inverter-based amplifier and the second inverter-based amplifier, and configured to receive the third input signal and the fourth input signal and to generate the first input signal and the second input signal;
wherein a first common-mode voltage of the first input signal and the second input signal is not equal to a second common-mode voltage of the third input signal and the fourth input signal.

15. The amplifier circuit of claim 14, wherein the level shifter comprises:
a first level shifter circuit coupled to the first inverter-based amplifier and the second inverter-based amplifier, and configured to receive the third input signal and to generate the first input signal; and
a second level shifter circuit coupled to the first inverter-based amplifier and the second inverter-based amplifier, and configured to receive the fourth input signal and to generate the second input signal.

16. The amplifier circuit of claim 14, wherein the level shifter is a first level shifter, the first inverter-based amplifier further receives a fifth input signal and a sixth input signal, and the amplifier circuit further comprises:
a second level shifter coupled to the first inverter-based amplifier, and configured to receive the first input signal and the second input signal and to generate the fifth input signal and the sixth input signal.

17. The amplifier circuit of claim 16, wherein the second inverter-based amplifier further receives a seventh input signal and an eighth input signal, and the amplifier circuit further comprises:
a third level shifter coupled to the second inverter-based amplifier, and configured to receive the seventh input signal and the eighth input signal and to generate the third input signal and the fourth input signal.

18. The amplifier circuit of claim 14, wherein the first inverter-based amplifier has a first node and a second node, the second inverter-based amplifier has a third node and a fourth node, the first node is coupled to the first voltage, the third node is coupled to the second voltage, and the amplifier circuit further comprises:
a bias control circuit coupled to the second node and the fourth node and configured to adjust at least one of a first intermediate voltage at the second node and a second intermediate voltage at the fourth node.

19. The amplifier circuit of claim 14, wherein the first inverter-based amplifier has a first node and a second node, the second inverter-based amplifier has a third node and a fourth node, the first node is coupled to the first voltage, the third node is coupled to the second voltage, and the amplifier circuit further comprises:
an amplifier coupled to the second node and the fourth node and configured to amplify the third input signal and the fourth input signal.

20. The amplifier circuit of claim 1, wherein the first inverter-based amplifier comprises:
a first transistor having a first source, a first gate, and a first drain, wherein the first source is coupled to the first voltage, and the first gate is the first input terminal;
a second transistor having a second source, a second gate, and a second drain, wherein the second source is coupled to the first voltage, and the second gate is the second input terminal;
a third transistor having a third source, a third gate, and a third drain, wherein the third source is coupled to the second voltage, and the third gate is the first input terminal;
a fourth transistor having a fourth source, a fourth gate, and a fourth drain, wherein the fourth source is coupled to the second voltage, and the fourth gate is the second input terminal;
a first cascode circuit coupled between the first drain and the fourth output terminal;
a second cascode circuit coupled between the second drain and the third output terminal;
a third cascode circuit coupled between the third drain and the fourth output terminal; and
a fourth cascode circuit coupled between the fourth drain and the third output terminal.
